(19) United States
(12) Patent Application Publication
(10) Pub. No.: US 2014/0083483 A1
(43) Pub. Date: Mar. 27, 2014

(54) SOLAR TILE

(71) Applicant: Zhengyuan Xu, Shanghai (CN)

(72) Inventor: Zhengyuan Xu, Shanghai (CN)

(21) Appl. No.: 14/113,559

(22) PCT Filed: May 16, 2012
(86) PCT No.: PCT/CN2012/075610

§ 371 Date: Oct. 23, 2013

(30) Foreign Application Priority Data
May 17, 2011 (CN) 201110127524.3
May 17, 2011 (CN) 201110127907.0
May 17, 2011 (CN) 201110128122.5

(51) Int. Cl. H01L 31/048; H01L 31/058

(52) U.S. Cl. CPC H01L 31/0483; H01L 31/058
USPC 136/248; 136/259

(57) ABSTRACT

The present invention relates to a photoelectrical and photo-thermal sunlight tile which has a waterproof performance as in ordinary tiles as well as a function of conducting photoelectrical and photo-thermal conversion. The sunlight tile comprises a solar energy converting assembly which converts light radiation of the solar energy into electrical energy and thermal energy and converts thermal radiation of the sunlight into thermal energy, whereby a utilization efficiency of the solar energy is substantially improved, a conversion loss rate is minimized and a conversion utilization rate is maximized.

### FIELD OF THE INVENTION

The present invention relates to the field of building, particularly to an improvement to a tile, and more particularly to a tile having both photovoltaic power generating and photo-thermal processing function.

### BACKGROUND OF THE INVENTION

Tiles are important roof waterproof materials, and are generally formed by baking clay or made of materials such as cement, and are shaped in an arch, planar or semi-cylindrical shape. In modern society, people are having higher and higher pursuit of comfortable building thermal environment so that energy consumption for building heating and air conditioning is increasing. In developed countries, energy used for building has already accounted for 30%-40% of a total energy consumption of the whole country, which imposes a certain restriction for economic development. Hence, people hope to apply solar energy technology to the building to lower energy used for the building. The tiles are usually laid on the top of a building and have excellent sunlight collecting performance. Hence, since 1970's, people have been attempting to install a solar cell panel on the tile surface to enable the tile to have a waterproof function as well as photovoltaic power generating capability.

The photovoltaic power generating system installed on a building is called BAPV (Building Attached Photovoltaic) system, usually used for secondary reconstruction of current buildings, and is a relatively early implementation mode of photovoltaic technology in building. However, upon application of BAPV technology, a supporting device used individually for supporting the solar cell panel is usually required, which increases costs and brings about trouble to installation. For example, if the solar cell panel is installed on the tiles, a supporting member for supporting the solar cell panel needs to be installed on the tile first, and then the solar cell panel is laid on the supporting member. Usually, a weight of the supporting member is by far greater than that of the solar cell panel, which raises a very high requirement for the bearing performance of the tile itself. Besides, since the supporting member is to be installed on the tile, the tile itself should have connection points for fixing the supporting member. The above situation limits the development of BAPV technology.

In view of the drawback in the above BAPV technology, people advance a technology wherein the photovoltaic power generating system is used as a part of an external maintenance structure of a building, and designed, constructed and installed along with the building. This technology is called solar BIPV (building integrated photovoltaic) technology. BIPV enables the building itself to have a structuring and material function as well as a photoelectrical converting function. For example, unlike the BAPV technology, a solar photovoltaic battery is integrated in a tile utilizing the BIPV technology, and the tile itself functions for support and an extra supporting member is not needed. The BIPV tile is installed and laid in substantially the same way as the ordinary tiles, and the only difference is that it integrates a waterproof function and the photovoltaic power generating function. BIPV is a main form of current photovoltaic building and extensively applied to all buildings capable of carrying the photovoltaic power generating system such as various civil buildings, public buildings and industrial buildings. Since the combination of the solar cell panel and the building does not occupy extra ground space, it is an optimal installation mode in which the photovoltaic power generating system is widely used in cities.

In current BIPV application, people have already noticed its advantages as follows:

1) it can generate in situ power which is used in situ so as to reduce expenditure and energy consumption during electrical current transmission;

2) it refrains the photovoltaic assembly array from occupying extra space and omits a supporting structure individually provided for the photoelectrical apparatus;

3) it uses novel building maintenance material, saves costly exterior ornamental materials, reduces the overall costs of the building and makes the building more aesthetically valuable;

4) since sunlight radiation intensity is substantially synchronous with the power consumption peak of the high-voltage power grid, the BIPV technology lessens a pressure of a power grid upon power consumption peak, eases the supply-demand contradiction of the power grid at the power consumption peak and valley and has a substantially great social benefit;

5) it avoids air pollution caused by fuel power generation.

Currently, the tile using the BIPV technology usually has a base panel and a main layer, wherein the main layer is attached to the base panel and comprises a solar cell panel or a solar cell assembly. The base panel is connected to the building. Usually, in the current solar tiles, the base panel is provided with a structure for connecting with the building roof, or an adhesive is used to directly adhere and fix the solar tile to the building roof. Being located on the building roof, the solar cell in the main layer can better absorb the sunlight at a suitable light receiving angle, and after the absorption of sunlight, the optical energy is converted to electrical energy which is merged into a household power grid system via an electrical output member disposed in the main layer or base panel to provide power for household life or directly connected to the power grid for transmission of power.

Currently, solar cells available in the market are mostly polycrystalline silicon cells and monocrystalline silicon cells. Such silicon cells has an photoelectrical converting efficiency of 13%-16% at a temperature of 25 centigrade degrees, and the sunlight which cannot be converted into electrical energy, after being absorbed by the cell, will cause the temperature at the surface of the cell to rise. In addition, in order to better absorb sunlight, the solar cell panel in the solar tile is directly exposed to the sunlight during operation, and thermal radiation of the sunlight causes the temperature of the whole solar tile too high. Due to action of heat conduction, the high temperature of the solar tile itself will affect its solar cell panel. However, a too high temperature will bring side effects to the working efficiency of the polycrystalline silicon cell or monocrystalline silicon cell. It is attested through experiment that after the working temperature of the cell exceeds its optimal working temperature, once the temperature rises by one centigrade degree, the open-circuit voltage falls about 2.0 mV-2.2 mV, and peak power loss rate is about 0.35%-0.45%. Besides, the short-circuiting current of the solar cell will rise along with the increase of the temperature. It can be seen that too high a temperature of the solar cell will adversely affect its converting efficiency and meanwhile quicken its attenuation speed and reduce its service life.

With respect to the above drawbacks, some people design a novel solar tile comprising a base panel and two main layers, wherein the first main layer comprises a solar cell or cell pack, the second main layer is provided with a thin storage having a heat carrier. The first main layer is disposed above the base panel, the second main layer is disposed below the base panel, the solar cell in the first main layer generates electrical energy by absorbing sunlight, the second main layer absorbs, via the heat carrier in the thin storage, heat generated by the sunlight tile frame directly absorbing sun thermal radiation, and the heat transfer member is used to supply and pre-heat the hot water in the household tap water pipe.

The above mode can carry away the heat produced by the sunlight tile frame due to sun thermal radiation, but it cannot eliminate the heat generated on the solar cell panel, including heat generated by solar energy thermal radiation on the cell panel and heat generated during photoelectrical conversion. In fact, besides the heat produced by sunlight directly radiating on the cell panel, since the photoelectrical converting efficiency of the solar cell panel is only 13%-16%, about 80% of sunlight radiation is directly converted into heat during the photoelectrical conversion. As such, the heat produced during photoelectrical conversion causes its surface temperature to rise, thereby affecting its converting efficiency. Further, since about 80% of sunlight radiation is converted into heat of the solar cells and can not be further utilized, the coefficient of utilization to the solar energy in the current sunlight tile is then very low.

### SUMMARY OF THE INVENTION

Therefore, it is advantageous to provide a sunlight tile which is configured to use solar energy to generate power and meanwhile cool the sunlight tile and a solar energy converting unit upon operation.

According to one aspect of the present invention, the present invention provides a sunlight tile, comprising: a tile body; a solar energy converting unit disposed on the tile surface and oriented in a way that its light receiving surface can receive sunlight so as to convert the solar energy into electrical energy by using its intrinsic property; a cooling unit supported by the tile body and disposed on a backlighting side of the solar energy converting unit opposite to the light receiving surface to simultaneously cool the tile body and the solar energy converting unit; an insulating heat conduction layer disposed between the solar energy converting unit and the cooling unit and configured to make the solar energy converting unit insulative relative to the cooling unit and transfer the heat of the solar energy converting unit to the cooling unit.

Since the cooling unit of the sunlight tile of the present invention can simultaneously cool the tile body and the solar energy converting unit, when the sunlight tile operates, the temperature of the tile body of the sunlight tile and the temperature of the solar energy converting unit will not rise excessively so that the solar energy converting unit can be maintained in an optimal working temperature and photovoltaic power generating efficiency can be ensured.

In a preferred embodiment of the present invention, the insulating heat conduction layer comprises a ceramic membrane layer making the solar energy converting unit insulative relative to the cooling unit and a metal heat conduction binding layer for seamlessly binding the ceramic membrane layer to the backlighting surface of the solar energy converting unit.

In this embodiment, the ceramic membrane layer makes the solar energy converting unit insulative relative to the cooling unit to avoid electrical energy loss. Meanwhile, since the metal heat conduction binding layer allows the ceramic membrane layer to be seamlessly bound to the backlighting surface of the solar energy converting unit, the insulating heat conduction layer can be ensured to effectively transfer heat generated during the photoelectrical conversion to the cooling unit.

In another preferred embodiment of the present invention, the solar energy converting unit comprises at least one silicon cell, wherein the backlighting surface of each silicon cell is applied on the metal heat conduction binding layer.

In the embodiment, the metal heat conduction binding layer improves electrical conductivity as compared with an optical grating welding mode in the prior art and can better transfer the heat energy of the cell out.

In a further preferred embodiment of the present invention, the tile body is formed of a refractory flame-retardant unsaturated modified synthetic engineering plastic.

In this embodiment, since the tile body is formed of a refractory flame-retardant unsaturated modified synthetic engineering plastic, it has properties such as resistance against high-temperature whether and flame retarding and meanwhile has properties such as a small specific gravity and a high strength.

In a further preferred embodiment of the present invention, the cooling unit comprises at least one refrigerant channel which extends parallel to the insulating heat conduction layer to absorb heat transferred from the solar energy converting unit via the insulating heat conduction layer, and which extends into a peripheral wall of the tile body to absorb the heat on the tile body generated by sunlight radiation. The refrigerant medium can be water, wind, oil, ice or gas.

In this embodiment, the refrigerant channel is in full contact with the tile body and the solar energy converting unit so that the refrigerant can be easily used to cool the tile body and the solar energy converting unit.

In another aspect of the present invention, there is provided a sunlight tile which is configured to use solar energy to generate power and meanwhile absorb radiated heat from the solar energy converting unit and the heat generated from photovoltaic power generation and heat generated on the tile body due to sunlight thermal radiation upon operation.

According to another aspect of the present invention, the present invention provides a sunlight tile, comprising: a tile body; a solar energy converting unit disposed on the tile surface and oriented in a way that its light receiving surface can receive sunlight so as to convert the solar energy into electrical energy by using its intrinsic property; a heat absorbing assembly supported by the tile body and disposed on a backlighting side of the solar energy converting unit opposite to the light receiving surface; an insulating heat conduction layer disposed between the solar energy converting unit and the heat absorbing assembly and configured to make the solar energy converting unit insulative relative to the heat absorbing assembly and simultaneously transfer the heat formed on the solar energy converting unit due to the sunlight thermal radiation and the heat generated from photovoltaic power generation; wherein the heat absorbing assembly simultaneously absorbs the heat transferred by the insulating heat conduction layer from the solar energy converting unit and heat generated on the tile body due to the sunlight thermal radiation.

Since the heat absorbing assembly of the sunlight tile of the present invention can simultaneously absorb the heat generated on the tile body and the solar energy converting unit due to sunlight thermal radiation and heat generated on the solar energy converting unit due to photovoltaic power generation, the heat absorbing assembly, on the one hand, cools the tile body and the solar energy converting unit, and on the other hand, can absorb not only the heat generated by solar energy thermal radiation but also the heat generated by photoelectrical power generation.

In a preferred embodiment, the heat absorbing assembly comprises an integrally formed groove plate having a heat conduction performance, wherein a circuitous channel is disposed in the groove plate, and a heat absorbing medium in the channel is oil.

In the embodiment, since the groove plate employs a heat conducting material, has the circuitous channel structure and uses oil as the medium, it can effectively absorb the heat of the solar energy converting unit and the tile body.

In another preferred embodiment, the channel has a wide sectional portion and a narrow sectional portion for slowing down a flow rate of the heat absorbing medium, wherein a sectional area of the narrow sectional portion is one third of a sectional area of the wide sectional portion.

Due to this structural arrangement, the heat absorbing medium in the channel will slow down when it flows to the narrow sectional portion so as to better absorb heat from the solar energy converting unit and the tile body.

In a further aspect of the present invention, there is provided a photoelectrical and photo-thermal sunlight tile which is configured to use solar energy to generate power, and meanwhile carry away radiated heat from the solar energy converting unit and the heat generated from photovoltaic power generation and heat generated on the tile body due to sunlight thermal radiation for use upon operation.

According to the further aspect of the present invention, the present invention provides a photoelectrical and photo-thermal sunlight tile, comprising: a tile body; a solar energy converting assembly supported on the tile body and comprising a photovoltaic power generating unit, a heat absorbing unit and an insulating heat conduction layer between the photovoltaic power generating unit and the heat absorbing unit, wherein the photovoltaic power generating unit is disposed on the tile surface and oriented in a way that its light receiving surface can receive sunlight so as to convert the optical energy into electrical energy by using its intrinsic property; the heat absorbing unit is supported by the tile body and disposed on a backlighting side of the photovoltaic power generating unit opposite to the light receiving surface to simultaneously absorb the heat formed on the tile body by the sunlight thermal radiation and heat generated by the photovoltaic power generating unit during photoelectrical conversion; the insulating heat conduction layer is disposed between the photovoltaic power generating unit and the heat absorbing unit and configured to make the photovoltaic power generating unit insulative relative to the heat absorbing unit and simultaneously transfer the heat formed on the photovoltaic power generating unit due to the sunlight thermal radiation and the heat generated by the photovoltaic power generating unit from photovoltaic power generation; wherein the heat absorbing unit simultaneously absorbs the heat transferred by the insulating heat conduction layer from the photovoltaic power generating unit and heat formed on the tile body due to the sunlight thermal radiation; an electrical output unit electrically connected with the photovoltaic power generating unit to receive electrical energy from the photovoltaic power generating unit and output it outside the sunlight tile in the form of electrical current; a heat transfer unit fluidly communicated with the heat absorbing unit to provide a heat absorbing medium for the heat absorbing unit and output the medium in the heat absorbing unit already absorbing heat outside the sunlight tile.

In this further aspect, the solar energy converting assembly can convert solar energy into electrical energy, use the electrical output unit to carry away the electrical energy in the form of electrical current, and simultaneously carry away the heat generated by sunlight radiation on the solar energy converting unit, the heat generated from photovoltaic power generation and heat generated on the tile body due to sunlight thermal radiation to complete heat transfer, thereby maximizing use of the light radiation and thermal radiation of the solar energy.

In a preferred embodiment, the photovoltaic power generating unit comprises a plurality of silicon cells which light receiving surface is a negative pole and which backlighting surface is a positive pole. A copper wire is provided on a light receiving surface of each silicon cell and extends to connect the backlighting surface of another silicon cell so as to form in-series connection between the silicon cells.

In this embodiment, by virtue of this in-series connection mode, electrical energy can be generated most efficiently so as to improve the photoelectrical conversion rate.

In another preferred embodiment, the solar energy converting unit comprises a plurality of silicon cells, wherein the backlighting surface of each silicon cell is applied on the metal heat conduction binding layer.

In this embodiment, the metal heat conduction binding layer improves electrical conductivity as compared with an optical grating welding mode in the prior art and can better transfer the heat energy of the cell out.

In a further preferred embodiment, a light permeable hydrophobic film layer is provided on a light receiving surface of the photovoltaic power generating unit. The arrangement of this film layer can ensure utilization of sunlight and prevent stay of water on the receiving surface of the photovoltaic power generating unit from affecting the photoelectrical and photo-thermal conversion.

In a further preferred embodiment, the heat absorbing unit comprises a passage, a passage outlet and a passage inlet. The heat transfer unit comprises a medium inlet communicated with the passage outlet of the heat absorbing unit and a medium outlet communicated with the passage inlet of the heat absorbing unit. The heat absorbing medium having absorbed heat enters the medium inlet of the heat transfer unit through the passage outlet of the heat absorbing unit and is outputted outside the sunlight tile for further heat exchange, and after these medium finish heat transfer through the further heat exchange, they flow back to the heat absorbing unit through the medium outlet of the heat transfer unit and the passage inlet of the heat absorbing unit.

In this embodiment, since the heat absorbing unit is in fluid communication with the heat transfer unit, the heat on the solar energy converting assembly and the tile body can be outputted in real time through the medium from the heat absorbing unit to the heat transfer unit to finish heat transfer, thereby effectively improving utilization rate of thermal energy.

In a further preferred embodiment, the passage inlet of the heat absorbing unit is located at a lower end of the tile body, and the passage outlet of the heat absorbing unit is located at an upper end of the sunlight tile.

In this embodiment, with the passage inlet being located below and the passage outlet being located above, it enables a cold medium such as oil to voluntarily flow from the lower end of the sunlight tile to the upper end of the sunlight tile to form a negative pressure of cold oil.

In a further preferred embodiment, the sunlight tile is further provided with a communication module which can be used to collect in real time information of a silicon chip and send out the information for external communication. The information can be converted electrical quantity of the silicon chip such as the generated electrical current and a surface temperature. For example, when a certain silicon chip on the sunlight tile or part of the tile is covered by a pollutant, because the light permeability weakens and the converted electrical quantity of the silicon chip will remarkably fall, people can quickly locate the silicon chip in question according to the real-time electrical quantity conversion information sent by the communication module of the silicon chip, and carry out corresponding treatment.

In a further aspect of the present invention, there is provided a photoelectrical and photo-thermal sunlight tile which is configured to use solar energy to generate power, and meanwhile carry away radiated heat from the solar energy converting unit of each sunlight tile and the heat generated from photovoltaic power generation and heat generated on the tile body due to sunlight thermal radiation upon operation for use.

According to this aspect of the present invention, there is provided a photoelectrical and photo-thermal sunlight tile group formed by connecting a plurality of the aforesaid photoelectrical and photo-thermal sunlight tiles, an electrical output unit of each sunlight tile is connected in series with the electrical output unit of another sunlight tile and then connected with an electrical output main line outside the sunlight tile, and meanwhile, the heat transfer unit of each of the sunlight tiles is connected in parallel with the heat transfer unit of another sunlight tile, and then connected with a heat exchange main line outside the sunlight tile.

In this aspect, the photoelectrical and photo-thermal sunlight tiles can be produced in groups or a plurality of tiles are assembled into a tile group so that their electrical energy output and thermal energy output can be conducted in a centralized way, thereby improving production and assembling efficiency.

In a preferred embodiment, the medium inlet of the heat transfer unit of each sunlight tile is connected with an inlet main line external of the sunlight tile group, and the medium outlet of the heat transfer unit of each of the sunlight tiles is connected with an outlet main line external of the sunlight tile group.

In this embodiment, since the heat transfer unit of each tile of the tile group has its medium inlet and medium outlet, and meanwhile there are provided unified inlet main line and outlet main line for centralizing them, assembling with other tile groups (if needed) is facilitated and the production and assembling efficiency are improved.

In a further preferred embodiment, a protrusion and/or recess of one sunlight tile can be embeddedly engaged in a recess and/or protrusion of adjacent tiles so that the tile is connected together with adjacent tiles.

In this embodiment, since the recess is engaged with the protrusion in an embedded manner, the sunlight tiles can be put next to one another to form a tile group, and the engagement in an embedded manner is relatively firm.

In a further preferred embodiment, a waterproof adhesive layer is provided on a surface of an engaging slot wherein the protrusion is embedded in the recess between tiles.

In this embodiment, the waterproof adhesive layer reinforces the connection between tiles and can diminish a stress at connections of tiles so that when the tiles are subjected to large external forces such as strong wind or tornado, connections of the tiles will not be damaged by wind pressure uplifting stress.

According to another object of the present invention, it is advantageous to provide a photovoltaic converting assembly which is configured to use solar energy to generate power and meanwhile cool the solar energy converting unit upon operation.

Therefore, the present invention provides a photovoltaic converting assembly, comprising: a solar energy converting unit oriented in a way that its light receiving surface is receivable of sunlight so as to convert the solar energy into electrical energy by means of its intrinsic property; a cooling unit disposed on a backlighting side of the solar energy converting unit opposite to the light receiving surface to cool the solar energy converting unit; an insulating heat conduction layer disposed between the solar energy converting unit and the cooling unit and configured to make the solar energy converting unit insulative relative to the cooling unit and transfer the heat of the solar energy converting unit to the cooling unit.

Since the insulating heat conduction layer of the photovoltaic converting assembly can transfer the heat on the solar energy converting unit, the cooling unit can cool the solar energy converting unit, as a result, the temperature of the solar energy converting unit will not rise excessively so that the solar energy converting unit can be maintained in an optimal working temperature and photovoltaic power generating efficiency can be ensured.

Preferably, the above photovoltaic converting assembly is embodied as a sunlight tile and further comprises a tile body; the solar energy converting unit being disposed on the tile surface; the cooling unit being supported by the tile body to simultaneously cool the tile body.

According to still another object of the present invention, it is advantageous to provide a photoelectrical and photo-thermal converting assembly which is configured to use solar energy to generate power and meanwhile carry away the radiated heat from the solar energy converting unit and the heat generated from photovoltaic power generation upon operation for further utilization.

Therefore, the present invention provides a photoelectrical and photo-thermal converting assembly, comprising: a solar energy converting assembly, an electrical output unit and a heat transfer unit, wherein the solar energy converting assembly comprising: a photovoltaic power generating unit oriented in a way that its light receiving surface is receivable of sunlight so as to convert optical energy into electrical energy by means of its intrinsic property; a heat absorbing unit disposed on a backlighting side of the photovoltaic power generating unit opposite to the light receiving surface to absorb heat generated by the photovoltaic power generating unit during photoelectrical conversion; an insulating heat conduction layer disposed between the photovoltaic power generating unit and the heat absorbing unit and configured to make the photovoltaic power generating unit insulative relative to the heat absorbing unit and simultaneously transfer the heat generated on the photovoltaic power generating unit due to the sunlight thermal radiation and the heat generated by the photovoltaic power generating unit from photovoltaic power generation to the heat absorbing unit; and wherein the electrical output unit electrically connected with the photovoltaic power generating unit to receive electrical energy from the photovoltaic power generating unit and output it outside the photoelectrical and photo-thermal converting assembly in the form of electrical current; the heat transfer unit fluidly communicated with the heat absorbing unit to provide a heat absorbing medium for the heat absorbing unit and output the medium in the heat absorbing unit already absorbing heat outside the photoelectrical and photo-thermal converting assembly.

In this aspect, the solar energy converting assembly can convert solar energy into electrical energy, and the electrical output unit is used to carry away the electrical energy in the form of electrical current, and the heat transfer unit is used to simultaneously carry away the heat generated by sunlight radiation on the solar energy converting unit and the heat generated from photovoltaic power generation due to sunlight thermal radiation to complete heat transfer, thereby maximizing use of the light radiation and thermal radiation of the solar energy.

Preferably, the above photoelectrical and photo-thermal converting assembly is embodied as a photoelectrical and photo-thermal sunlight tile and further comprises a tile body; the solar energy converting assembly being supported by the tile; the photovoltaic power generating unit of the solar energy converting assembly being disposed on the tile surface; the heat absorbing unit being supported by the tile body to simultaneously absorb the heat on the tile body generated by sunlight radiation.

According to further still another object of the present invention, it is advantageous to provide a photoelectrical and photo-thermal module group.

Therefore, the present invention provides a photoelectrical and photo-thermal module group formed by connecting a plurality of the above photoelectrical and photo-thermal converting assemblies, the electrical output unit of each photoelectrical and photo-thermal converting assemblies is connected in series with the electrical output unit of another photoelectrical and photo-thermal converting assemblies and then connected with an electrical output main line outside the photoelectrical and photo-thermal converting assemblies, and meanwhile, the heat transfer unit of each of the photoelectrical and photo-thermal converting assemblies is connected in parallel with the heat transfer unit of another photoelectrical and photo-thermal converting assemblies, and then connected with a heat exchange main line outside the photoelectrical and photo-thermal converting assemblies.

In this aspect, the photoelectrical and photo-thermal module group can be produced in groups or a plurality of photoelectrical and photo-thermal converting assemblies are assembled into a group so that their electrical energy output and thermal energy output can be conducted in a centralized way, thereby improving production and assembling efficiency.

These aspects and other aspects of the present invention will be clearly illustrated with reference to the embodiments described hereunder.

### BRIEF DESCRIPTION OF DRAWINGS

The structure and operation modes and objectives and advantages of the present invention will be made more apparent by the following depictions with reference to drawings, wherein the same reference numbers denote the same elements.

FIG. 1 is a cross sectional view of a sunlight tile according to a first embodiment of the present invention;

FIG. 2 is a cross sectional view of a sunlight tile according to a second embodiment of the present invention;

FIG. 3 is a schematic view of an oil groove plate in the sunlight tile of FIG. 2;

FIG. 4 is a cross sectional view of a sunlight tile according to a third embodiment of the present invention;

FIG. 5 is a schematic perspective view of the sunlight tile of FIG. 4 as viewed downwardly, wherein arrangement of silicon chips are not shown for the sake of clarity;

FIG. 6 is a schematic top view of the sunlight tile of FIG. 4;

FIG. 7 is a schematic view showing connection of silicon chips on the sunlight tile of FIG. 4, wherein silicon chips in each series are connected in series and meanwhile series of silicon chips are connected to series of silicon chips in series;

FIG. 8 is a schematic view of an embodiment of a sunlight tile set of the present invention, showing a tile set structure comprising four tiles.

### DETAILED DESCRIPTION OF PREFERRED EMBODIMENTS

As required, specific embodiments of the present invention will be revealed here. However, it should be appreciated that embodiments revealed here are only typical examples of the present invention and the present invention can be embodied in various forms. Therefore, details revealed here are not considered as being limiting and only serve as a basis of claims and a typical basis for teaching those skilled in the art to differently apply the present invention in any suitable manner in practice, including use of various features revealed herein and combination of features that might not explicitly be revealed herein.

In general, first of all the present invention provides a photovoltaic converting assembly which can use solar energy to generate power and meanwhile cool the solar energy converting or photovoltaic converting unit by a cooling unit so as to ensure the photoelectric transformation efficiency.

Secondly, the present invention further provides a photoelectrical and photo-thermal converting assembly which can convert solar energy into electrical energy, and can absorb the heat generated on the solar energy converting or photovoltaic converting unit so as to cool them and meanwhile carry away the heat for complete heat transfer and utilization.

Further, the present invention provides a sunlight tile which is capable of converting solar energy into electrical energy, and which meanwhile generates heat including heat produced during photovoltaic conversion and heat produced from sunlight radiation on a solar energy converting unit or photoelectric converting unit and a tile body. Therefore, according to one aspect of the present invention, a cooling unit is provided in a sunlight tile to cool the solar energy converting unit or photoelectric converting unit and the tile body to ensure the photoelectric converting efficiency; according to a second aspect of the present invention, a heat absorbing assembly is provided in the sunlight tile to absorb heat on the solar energy converting unit or photoelectric converting unit and the tile body so as to cool them; according to a third aspect of the present invention, both a heat absorbing unit and a heat transfer unit are provided to absorb heat on the solar energy converting unit or photoelectric converting unit and the tile body and meanwhile take heat away for heat exchange and utilization.

The above photovoltaic converting assembly can be used for any photovoltaic converting system, and the above photoelectrical and photo-thermal converting assembly can be used for any solar power system, such as solar tile, solar curtain wall, solar water heater or photovoltaic power generating system. In the embodiment herein below, the photovoltaic converting assembly or the photovoltaic and photo-thermal converting assembly is embodied as a sunlight tile.

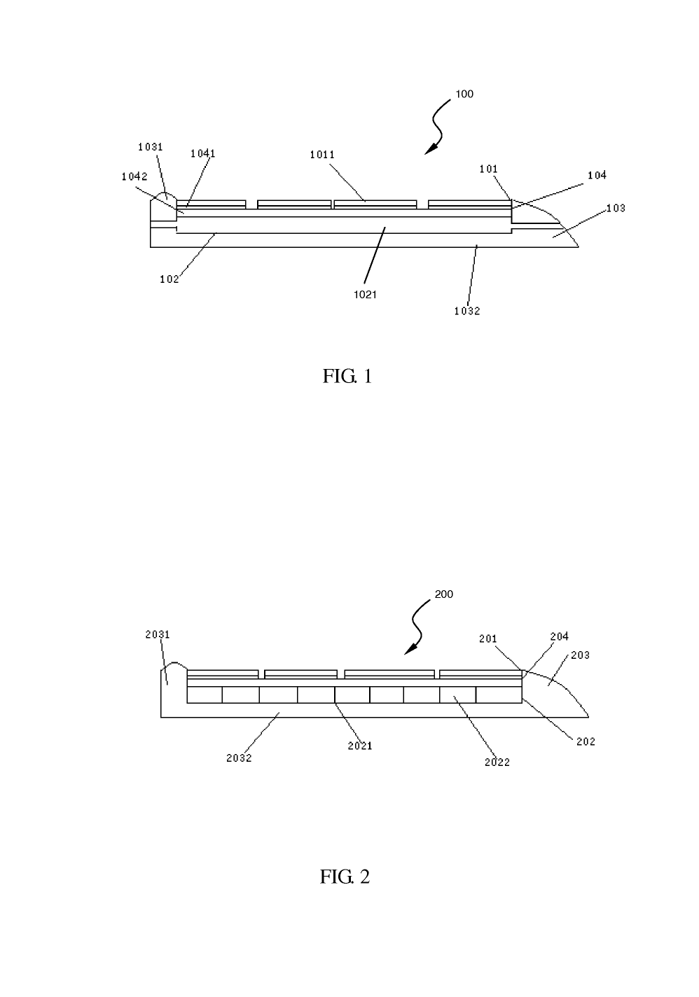

FIG. 1 shows a first embodiment of a sunlight tile of the present invention. The sunlight tile 100 comprises: a solar energy converting unit 101, a cooling unit 102, an insulating heat conduction layer 104 and a tile body 103.

The tile body 103 can be integral and molded of a refractory flame-retardant unsaturated modified synthetic engineering plastic.

As shown in FIG. 1, the solar energy converting unit 101 is disposed on a surface of the tile and can be a single silicon cell or an array comprised of a plurality of silicon cells 1011, and a light permeable hydrophobic film layer (not shown) can be provided on a light receiving surface of the solar energy converting unit 101.

The insulating heat conduction layer 104 comprises a ceramic membrane layer 1041 and a metal heat conduction binding layer 1042, wherein the metal heat conduction binding layer 1042 can be formed of conductive silver paste. A backlighting surface of each silicon cell 1011 is applied to a screen printed metal heat conduction binding layer 1042 so that the metal heat conduction binding layer 1042 can seamlessly bound to the solar energy converting unit 101. Furthermore, an area of each metal heat conduction binding layer 1042 is not greater than an area of the backlighting surface of the silicon cell 1011 applied thereto.

The cooling unit 102 is supported by the tile body 103 and disposed on the side of the backlighting surface of the solar energy converting unit 101. The cooling unit 102 comprises at least one refrigerant channel 1021 which extends parallel to the insulating heat conduction layer 104. On the one hand, the refrigerant channel 1021 contacts a bottom portion 1012 of the solar energy converting unit and, on the other hand, contacts a peripheral wall 1031 and a bottom section 1032 of the tile body 103.

In an embodiment, cold water flows in the refrigerant channel 1021 so that when the sunlight tile 100 operates, the refrigerant channel 1021 cools the tile body 103 via the cold water circulating therein on the one hand, and on the other hand, heat of the solar energy converting unit is first transferred by the insulating heat conduction layer to the refrigerant channel 1021, and the refrigerant channel 1021 lowers the transferred heat via the cold water. In this embodiment, the refrigerant channel can be disposed in a snake shape.

In another embodiment of the present invention, the refrigerant channel 1021 can be associated with an air-cooling system (not shown) such that cold wind blown out of the air-cooling system can quickly circulate in the refrigerant channel 1021 to blow away the heat on the tile body 103 and the solar energy converting unit 101.

In another embodiment of the present invention, solid media capable of releasing cold air, such as dry ice can be disposed in the refrigerant channel 1201, and these solid media are respectively disposed at locations where the refrigerant channel 1021 contacts the insulating heat conduction layer 104 and the peripheral wall 1031 and a bottom section 1032 of the tile body to simultaneously cool the tile body 103 and the solar energy converting unit 101.

As shown in FIG. 2, in the second embodiment of the present invention, the sunlight tile 200 comprises a solar energy converting unit 201, a heat absorbing assembly 202, an insulating heat conduction layer 204 and a tile body 203.

The sunlight tile in the second embodiment is substantially identical with the tile body in the first embodiment in structure, and the only thing is that the heat absorbing assembly 202 replaces the cooling unit 102 of the first embodiment. The heat absorbing assembly 202 is supported by the tile body 203 and disposed on a backlighting surface of the solar energy converting unit 201. As shown in FIG. 2, the heat absorbing assembly 202 can be an integrally formed groove plate 2021 which can be an aluminum substrate, so it has a good heat conduction performance.

In one embodiment of the present invention, the groove plate 2021 can be a transverse through groove which is wholly recessed, a thickness of the through groove is by far smaller than its length, and oil or water flows in the through groove. Since the groove plate 2021 is in full contact with the insulating heat conduction layer 204 and the tile body 203, so it can simultaneously absorb heat transferred from the insulating heat conduction layer and heat generated on the tile body due to sunlight thermal radiation.

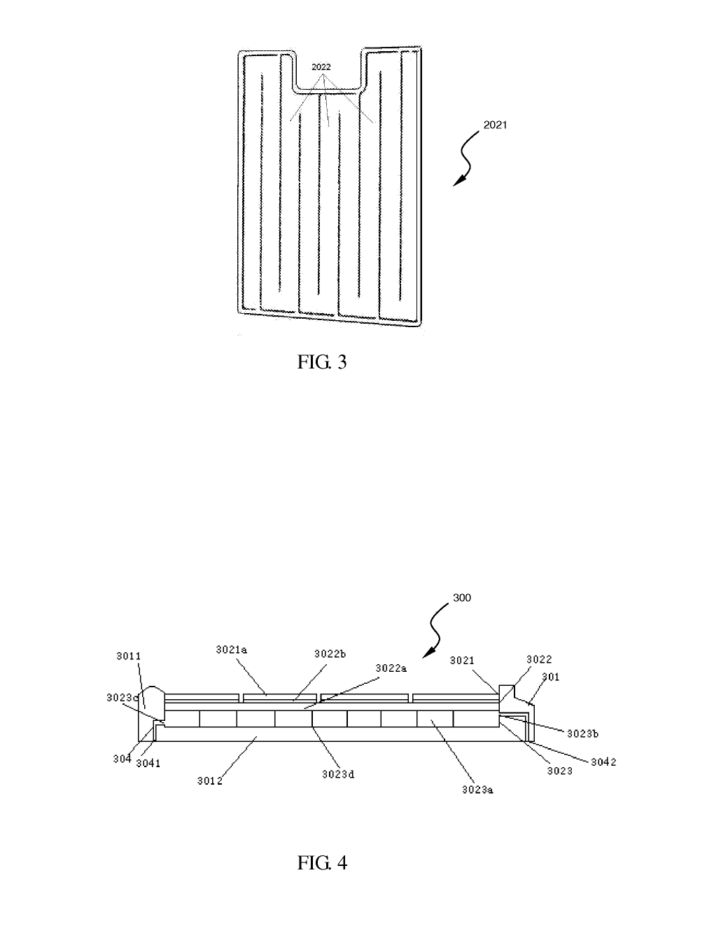

In a further embodiment of the present invention, as shown in FIG. 2 or FIG. 3, a circuitous channel 2022 is disposed in the groove plate 2021, and the channel 2022 can be arranged in a snake shape. Anti-oxidization anti-freeze heat transfer oil flows in the channel 2022. In order to enable the anti-oxidization anti-freeze heat transfer oil in the channel 2022 to sufficiently absorb heat, a sectional area of a narrow section of the channel 2022 is one third of a sectional area of a wide section thereof.

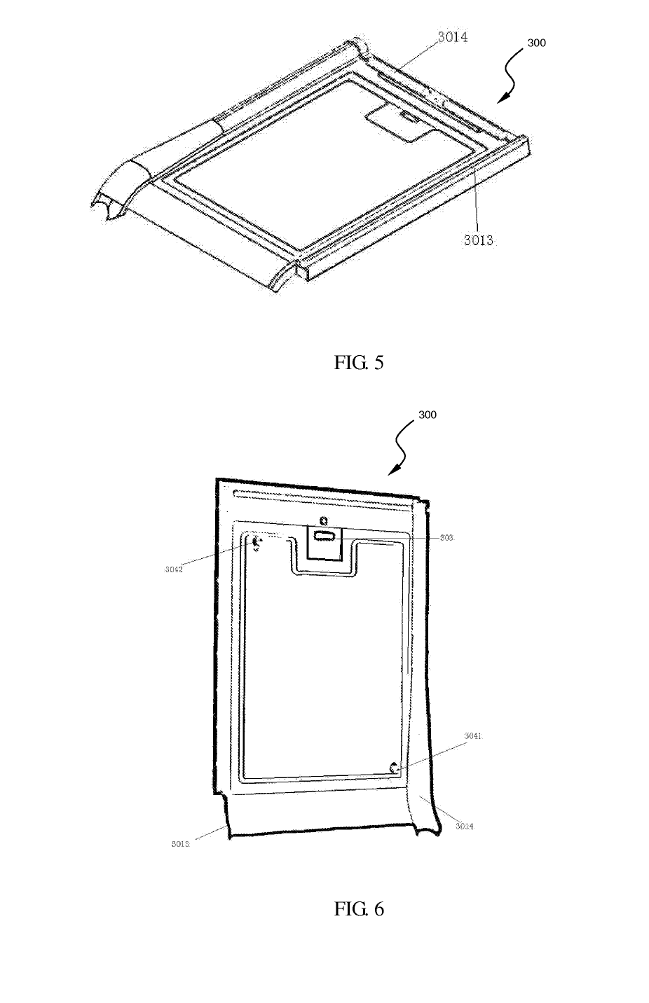

As shown in FIGS. 4-6, in a third embodiment of the present invention, the sunlight tile 300 comprises a tile body 301, a solar energy converting assembly 302, an electrical output unit 303 and a heat transfer unit 304.

As shown in FIG. 4, the solar energy converting assembly 302 is supported by the tile body 301 and comprises a photovoltaic power generating unit 3021, an insulating heat conduction layer 3022 and a heat absorbing unit 3023.

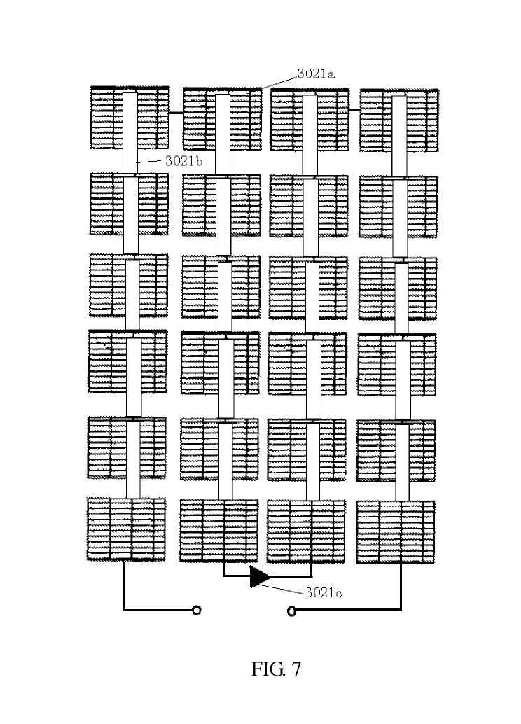

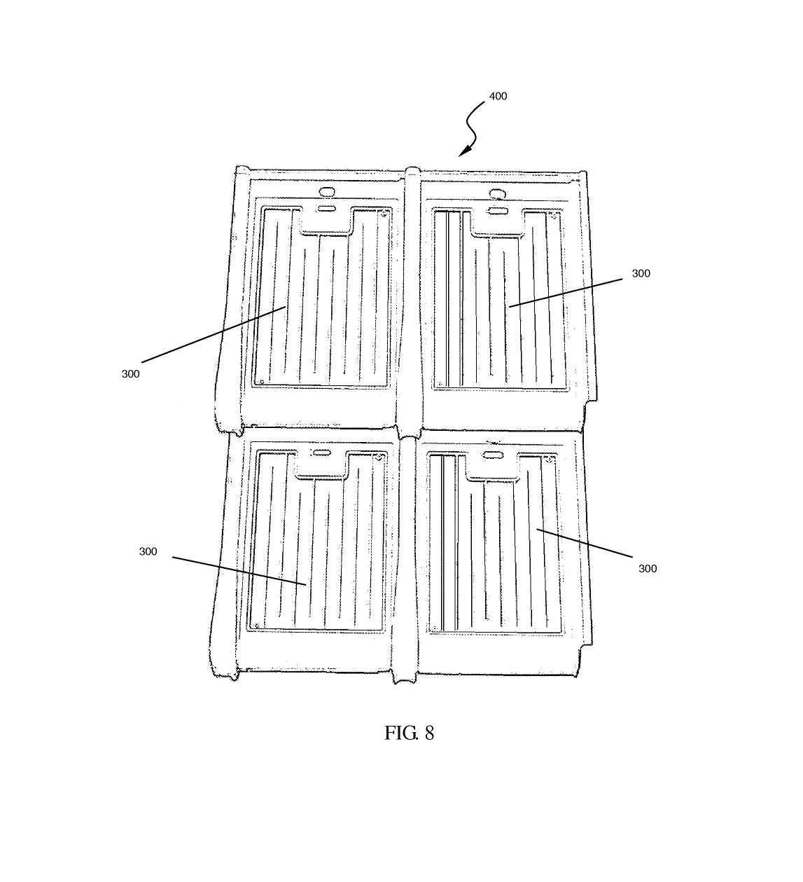

As shown in FIGS. 5 and 7, the photovoltaic power generating unit 3021 is disposed on the surface of the tile body 301, and its light receiving surface may have a light permeable hydrophobic film layer (not shown). The photovoltaic power generating unit 3021 comprises a plurality of silicon cells 3021a which light receiving surface is a negative pole and which backlighting surface is a positive pole. The plurality of silicon cells 3021a are connected together in series. For example, as shown in FIG. 7, in an array with four columns and six lines of silicon cells, the plurality of silicon cells in each column are connected together in series, then the silicon cell in the first line and first column is electrically connected to the silicon cell in the first line and second column, the silicon cell in the first line and third column is electrically connected to the silicon cell in the first line and fourth column, the negative pole of the silicon cell in the sixth line and first column is connected to the positive pole of the electrical output unit 303, the positive pole of the silicon cell in the sixth line and fourth column is connected to the negative pole of the electrical output unit 303, and the silicon cell in the sixth line and second column is electrically connected to the silicon cell in the sixth line and third column via a diode. The in-series connection between the silicon cells 3021a is achieved by a conductive copper wire provided on the light receiving surface thereof, and the conductive copper wire extends from the light receiving surface of the silicon cell to the backlighting surface of another silicon cell.

The insulating heat conduction layer 3022 comprises a ceramic membrane layer 3022a and a metal heat conduction binding layer 3022b, wherein the metal heat conduction binding layer 3022b may be formed of conductive silver paste. A backlighting surface of each silicon cell 3021a is applied to a screen printed metal heat conduction binding layer 3022b so that the metal heat conduction binding layer 3022b can seamlessly bound to the photovoltaic power generating unit 3021. Furthermore, an area of each metal heat conduction binding layer 3022b is not greater than an area of the backlighting surface of the silicon cell 3021a applied thereto.

As shown in FIG. 3, the heat transfer unit 304 is connected to the heat absorbing unit 3023 to provide a heat absorbing medium for the heat absorbing unit 3023, and outputs the medium already absorbing heat in the heat absorbing unit 3023 out of the sunlight tile. The heat absorbing unit 3023 comprises a passage, a passage outlet 3023b and a passage inlet 3023c. A medium inlet 3041 of the heat transfer unit 304 is communicated with the passage inlet 3023c, and a medium outlet 3042 of the heat transfer unit 304 is communicated with the passage outlet 3023b. The heat absorbing medium flows through the passage inlet 3023c into the passage 3023b, and flows, upon completion of absorption of heat, out of the passage outlet 3023b and then is outputted out of the sunlight tile via the heat transfer unit 304. Besides, in order to enable the heat exchange medium to form self-circulation in the passage, as shown in FIG. 6 the passage inlet 3023c and the medium inlet 3041 may be located at a lower end of the sunlight tile, and both the passage outlet 3023b and the medium outlet 3042 may be located at an upper end of the sunlight tile.

In an embodiment of the present invention, the heat absorbing medium after having absorbed heat is outputted via the heat transfer unit 304 to an external heat exchange passageway for further heat exchange to complete the heat transfer. Upon completion of further heat exchange of these media, they flow back into the heat absorbing unit 3023 through the medium inlet 3041 of the heat transfer unit 304 and the passage inlet 3023c of the heat absorbing unit 3023.

The heat absorbing unit 3023 can employ the groove plate of the second embodiment, and the groove plate 3023d is an aluminum substrate. A circuitous channel 3023a is disposed in the groove plate 3023d as the passage of the heat absorbing unit 3023, and the circuitous channel 3023a can be arranged in a snake shape. A sectional area of a narrow section of the channel 3023a is one third of a sectional area of a wide section thereof. Anti-oxidization anti-freeze heat transfer oil flows in the channel 3023a.

In addition, the sunlight tile 300 of the present invention is further provided with a communication module which can collect in real time information of a silicon chip it corresponds to and send the information. The information can be a surface temperature, converted quantity of power and so on. For example, when a certain silicon chip on the sunlight tile is covered by a pollutant, because the light permeability weakens and the converted electrical quantity of the silicon chip will remarkably fall, people can quickly locate the silicon chip in question according to the real-time electrical quantity conversion information sent by the communication module of the silicon chip, and carry out corresponding treatment.

The sunlight tile 300 of the present invention can be used individually and installed on a roof of a building, a plurality of tiles 300 can be connected together as a group and then used and installed. For example, four or eight tiles 300 can be connected together to form a tile group 400, and then these tile groups are installed on the roof.

In an embodiment of the sunlight tile group 400 of the present invention, the sunlight tile group comprises a plurality of sunlight tiles 300, an electrical output unit 303 of each sunlight tile 300 is connected in series with the electrical output unit 303 of another sunlight tile 300 and then connected with an electrical output main line outside the sunlight tile, and meanwhile, the heat transfer unit 304 of each of the sunlight tiles is connected in parallel with the heat transfer unit 304 of another sunlight tile, and then connected with a heat exchange main line outside the sunlight tile.

As shown in FIG. 6, the medium inlet 3041 of the heat transfer unit 304 of each sunlight tile 300 is communicated with an inlet main line external of the sunlight tile group, and the medium outlet of the heat transfer unit 304 of each of the sunlight tiles is connected with an outlet main line external of the sunlight tile group.

In an embodiment of the present invention, screw holes may be provided at the periphery of the sunlight tiles, and then these sunlight tiles 300 are connected together via screws. Alternatively, these sunlight tiles 300 are stacked together in a conventional tile stacking manner, and an adhesive is applied to enhance connection strength between tiles 300.

In a further embodiment of the present invention, as shown in FIG. 5 or FIG. 6, a protrusion 3013 is provided respectively on a lower side and a right side of the tile body 301 of the sunlight tile 3, and a recess 3014 is provided respectively at an upper side and a left side of the tile body. The protrusion 3013 at the lower side of the sunlight tile is capable of engaging with the recess 3014 at the upper side of the underlying tile, and the protrusion 3013 at the right side thereof is capable of engaging with the recess 3014 at the left side of the tile on the right, and so on so forth, the tile can be embedded and engaged with adjacent tiles around it. Besides, a waterproof adhesive layer is provided on a surface of an engaging slot wherein the protrusion 3013 is embedded in the recess 3014.

The tile of the present invention can be in any shape such as rectangle, square or arch. In addition, the embodiments of the present invention relate to photoelectrical and photo-thermal tiles, it should be appreciated that the present invention can be used for any roof structure, for example, the tile of the present invention can be directly bridged over a top beam of the roof to become the roof of the house, or as in BAPV technology, the tile of the present invention is installed on the tiles on the roof. Besides, although the present invention only mentions the tile in embodiments, those skilled in the art should understand, according to what is revealed in the present invention, that the tile can be applied to various building materials such as a curtain wall in BIPV field.

The technical contents and technical features of the present invention are already revealed as above. However, it should be appreciated that as guided by the creation idea of the present invention, those skilled in the art can make various modifications and improvements to the above structure, including combinations of technical features individually revealed herein or sought for protection, obviously including other combinations of these features, and other alternative types of solar energy converting units or photovoltaic power generating unit. Also, materials and structures have many possible variations. These variations and/or combinations all fall within the technical field to which the present invention relates to and fall within the protection scope of claims of the present invention. It is noticeable that according to practice, a single element used in claims means comprising one or more such elements.

1. A sunlight tile, comprising:
a tile body;
a solar energy converting unit disposed on a surface of the tile and oriented in a way that a light receiving surface of the solar energy converting unit is configured to receive sunlight so as to convert solar energy into electrical energy;
a cooling unit supported by the tile body and disposed on a backlighting side of the solar energy converting unit opposite to the light receiving surface to simultaneously cool the tile body and the solar energy converting unit;
an insulating heat conduction layer disposed between the solar energy converting unit and the cooling unit and configured to make the solar energy converting unit insulative relative to the cooling unit and transfer the heat of the solar energy converting unit to the cooling unit.

2. The sunlight tile according to claim 1, wherein the insulating heat conduction layer comprises a ceramic membrane layer making the solar energy converting unit insulative relative to the cooling unit and a metal heat conduction binding layer for seamlessly binding the ceramic membrane layer to the backlighting surface of the solar energy converting unit.

3. The sunlight tile according to claim 2, wherein the solar energy converting unit comprises at least one silicon cell.

4. The sunlight tile according to claim 3, wherein the backlighting surface of each silicon cell is applied on the metal heat conduction binding layer.

5. The sunlight tile according to claim 3, wherein the backlighting surface of each silicon cell is applied to a screen printed metal heat conduction binding layer.

6. The sunlight tile according to claim 5, wherein an area of each metal heat conduction binding layer is not greater than an area of the backlighting surface of the silicon cell applied thereto.

7. The sunlight tile according to any one of claim 2-6, wherein the metal heat conduction binding layer is formed of conductive silver paste.

8. The sunlight tile according to claim 1, wherein the tile body is formed of a refractory flame-retardant unsaturated modified synthetic engineering plastic.

9. The sunlight tile according to claim 8, wherein the tile body is integrally formed.

10. The sunlight tile according to claim 1, wherein the cooling unit comprises at least one refrigerant channel which extends parallel to the insulating heat conduction layer to absorb heat transferred from the solar energy converting unit via the insulating heat conduction layer, and which extends into a peripheral wall of the tile body to absorb the heat on the tile body generated by sunlight radiation.

11. The sunlight tile according to claim 10, wherein the cooling unit comprises a snake-shaped refrigerant channel.

12. The sunlight tile according to claim 11, wherein the light receiving surface of the solar energy converting unit has a light permeable hydrophobic film layer.

13. A sunlight tile, comprising:
a tile body;
a solar energy converting unit disposed on a surface of the tile and oriented in a way that a light receiving surface of the solar energy converting unit is configured to receive sunlight so as to convert solar energy into electrical energy;
a heat absorbing assembly supported by the tile body and disposed on a backlighting side of the solar energy converting unit opposite to the light receiving surface;
an insulating heat conduction layer disposed between the solar energy converting unit and the heat absorbing assembly and configured to make the solar energy converting unit insulative relative to the heat absorbing assembly and simultaneously transfer the heat generated on the solar energy converting unit due to the sunlight thermal radiation and the heat generated from photovoltaic power generation;
wherein the heat absorbing assembly simultaneously absorbs the heat transferred by the insulating heat conduction layer from the solar energy converting unit and heat generated on the tile body due to the sunlight thermal radiation.

14. The sunlight tile according to claim 13, wherein the light receiving surface of the solar energy converting unit has a light permeable hydrophobic film layer.

15. The sunlight tile according to claim 13, wherein the insulating heat conduction layer comprises a ceramic membrane layer making the solar energy converting unit insulative relative to the heat absorbing assembly and a metal heat conduction binding layer for seamlessly binding the ceramic membrane layer to the backlighting surface of the solar energy converting unit.

16. The sunlight tile according to claim 15, wherein the solar energy converting unit comprises at least one silicon cell, and the backlighting surface of each silicon cell is applied on the metal heat conduction binding layer.

17. The sunlight tile according to claim 16, wherein the backlighting surface of each silicon cell is applied to a screen printed metal heat conduction binding layer.

18. The sunlight tile according to claim 17, wherein an area of each metal heat conduction binding layer is not greater than an area of the backlighting surface of the silicon cell applied thereto.

19. The sunlight tile according to claims 15, wherein the metal heat conduction binding layer is formed of conductive silver paste.

20. The sunlight tile according to claim 15, wherein the heat absorbing assembly comprises an integrally formed groove plate having a heat absorbing medium therein.

21. The sunlight tile according to claim 20, wherein the groove plate is a metal groove plate having a heat conducting performance.

22. The sunlight tile according to claim 20, wherein the groove plate is an aluminum substrate.

23. The sunlight tile according to claims 20, wherein a circuitous channel is disposed in the groove plate, and the heat absorbing medium is located in the channel.

24. The sunlight tile according to claim 23, wherein the channel is arranged in a snake shape.

25. The sunlight tile according to claim 23, wherein the channel has a wide sectional portion and a narrow sectional portion for slowing down a flow rate of the heat absorbing medium.

26. The sunlight tile according to claim 25, wherein a sectional area of the narrow sectional portion is one third of a sectional area of the wide sectional portion.

27. The sunlight tile according to claim 20, wherein the heat absorbing medium is oil.

28. The sunlight tile according to claim 27, wherein the oil is anti-oxidization anti-freeze heat transfer oil.

29. The sunlight tile according to claim 28, wherein the tile body is molded of a refractory flame-retardant unsaturated modified synthetic engineering plastic.

30. A photoelectrical and photo-thermal sunlight tile, comprising:
a tile body;
a solar energy converting assembly supported on the tile body and comprising:
a photovoltaic power generating unit disposed on a surface of the tile boy and oriented in a way that a light receiving surface of the photovoltaic power generating unit is configured to receive sunlight so as to convert optical energy into electrical energy;
a heat absorbing unit supported by the tile body and disposed on a backlighting side of the photovoltaic power generating unit opposite to the light receiving surface to simultaneously absorb the heat generated on the tile body by the sunlight thermal radiation and heat generated by the photovoltaic power generating unit during photoelectrical conversion;
an insulating heat conduction layer disposed between the photovoltaic power generating unit and the heat absorbing unit and configured to make the photovoltaic power generating unit insulative relative to the heat absorbing unit and simultaneously transfer the heat generated on the photovoltaic power generating unit due to the sunlight thermal radiation and the heat generated by the photovoltaic power generating unit from photovoltaic power generation to the heat absorbing unit;
wherein the heat absorbing unit simultaneously absorbs the heat transferred by the insulating heat conduction layer from the photovoltaic power generating unit and heat generated on the tile body due to the sunlight thermal radiation;
an electrical output unit electrically connected with the photovoltaic power generating unit to receive electrical energy from the photovoltaic power generating unit and output it outside the sunlight tile in the form of electrical current;
a heat transfer unit fluidically communicated with the heat absorbing unit to provide a heat absorbing medium for the heat absorbing unit and output the medium in the heat absorbing unit already absorbing heat outside the sunlight tile.

31. The photoelectrical and photo-thermal sunlight tile according to claim 30, wherein the insulating heat conduction layer comprises a ceramic membrane layer making the photovoltaic power generating unit insulative relative to the heat absorbing unit and a metal heat conduction binding layer for seamlessly binding the ceramic membrane layer to the backlighting surface of the photovoltaic power generating unit.

32. The photoelectrical and photo-thermal sunlight tile according to claim 31, wherein the photovoltaic power generating unit comprises at least one silicon cell which light receiving surface is a negative pole and which backlighting surface is a positive pole.

33. The photoelectrical and photo-thermal sunlight tile according to claim 32, wherein the solar energy converting unit comprises a plurality of silicon cells which are connected in series.

34. The photoelectrical and photo-thermal sunlight tile according to claim 32, wherein a copper wire is provided on the light receiving surface of each silicon cell and extends to connect the backlighting surface of another silicon cell so as to form in-series connection between the silicon cells.

35. The photoelectrical and photo-thermal sunlight tile according to claims 32, wherein the backlighting surface of each silicon cell is applied on the metal heat conduction binding layer.

36. The photoelectrical and photo-thermal sunlight tile according to claim 35, wherein the backlighting surface of each silicon cell is applied to a screen printed metal heat conduction binding layer.

37. The photoelectrical and photo-thermal sunlight tile according to claim 36, wherein an area of each metal heat conduction binding layer is not greater than an area of the backlighting surface of the silicon cell applied thereto.

38. The photoelectrical and photo-thermal sunlight tile according to claims 31, wherein the metal heat conduction binding layer is formed of conductive silver paste.

39. The photoelectrical and photo-thermal sunlight tile according to claim 30, wherein the light receiving surface of the photovoltaic power generating unit has a light permeable hydrophobic film layer.

40. The photoelectrical and photo-thermal sunlight tile according to claim 30, wherein the heat absorbing unit comprises a passage, a passage outlet and a passage inlet, the heat transfer unit comprises a medium inlet communicated with the passage outlet of the heat absorbing unit and a medium outlet communicated with the passage inlet of the heat absorbing unit.

41. The photoelectrical and photo-thermal sunlight tile according to claim 40, wherein the heat absorbing medium having absorbed heat enters the medium inlet of the heat transfer unit through the passage outlet of the heat absorbing unit and is outputted outside the sunlight tile for further heat exchange, and after these medium finish heat transfer through the further heat exchange, they flow back to the heat absorbing unit through the medium outlet of the heat transfer unit and the passage inlet of the heat absorbing unit.

42. The photoelectrical and photo-thermal sunlight tile according to claim 40, wherein the heat absorbing unit comprises an integrally formed groove plate, a circuitous channel is disposed in the groove plate so that when the heat exchange medium flows through the channel, it absorbs thermal energy from the photovoltaic power generating unit and the tile body.

43. The photoelectrical and photo-thermal sunlight tile according to claim 42, wherein the groove plate is a metal plate having a heat conducting performance.

44. The photoelectrical and photo-thermal sunlight tile according to claim 43, wherein the groove plate is an aluminum substrate.

45. The photoelectrical and photo-thermal sunlight tile according to claim 42, wherein the circuitous channel is arranged in a snake shape.

46. The photoelectrical and photo-thermal sunlight tile according to claim 45, wherein the channel has a wide sectional portion and a narrow sectional portion for slowing down a flow rate of the heat absorbing medium.

47. The photoelectrical and photo-thermal sunlight tile according to claim 46, wherein a sectional area of the narrow sectional portion is one third of a sectional area of the wide sectional portion.

48. The photoelectrical and photo-thermal sunlight tile according to claims 30, wherein the heat absorbing medium is oil.

49. The photoelectrical and photo-thermal sunlight tile according to claim 48, wherein the oil is anti-oxidization anti-freeze heat transfer oil.

50. The photoelectrical and photo-thermal sunlight tile according to claim 40, wherein the passage inlet of the heat absorbing unit is located at a lower end of the tile body, and the passage outlet of the heat absorbing unit is located at an upper end of the sunlight tile.

51. The photoelectrical and photo-thermal sunlight tile according to claim 50, wherein the tile body is molded of a refractory flame-retardant unsaturated modified synthetic engineering plastic.

52. The photoelectrical and photo-thermal sunlight tile according to claim 30, further comprising a communication module.

53. The photoelectrical and photo-thermal sunlight tile according to claim 52, the electrical output unit of each sunlight tile is connected in series with the electrical output unit of another sunlight tile and then connected with an electrical output main line outside the sunlight tile, and meanwhile, the heat transfer unit of each of the sunlight tiles is connected in parallel with the heat transfer unit of another sunlight tile, and then connected with a heat exchange main line outside the sunlight tile.

54. The photoelectrical and photo-thermal sunlight tile group according to claim 53, wherein the medium inlet of the heat transfer unit of each sunlight tile is connected with an inlet main line external of the sunlight tile group, and the medium outlet of the heat transfer unit of each of the sunlight tiles is connected with an outlet main line external of the sunlight tile group.

55. The photoelectrical and photo-thermal sunlight tile group according to claim 54, wherein a protrusion and/or recess of one sunlight tile is engaged with a recess and/or protrusion of adjacent tiles so that the tile is connected together with adjacent tiles.

56. The sunlight tile group according to claim 55, wherein a waterproof adhesive layer is provided on a surface of an engaging slot wherein the protrusion is embedded in the recess.

57. A photovoltaic converting assembly, comprising:
a solar energy converting unit oriented in a way that a light receiving surface of the solar energy converting unit is configured to receive sunlight so as to convert the solar energy into electrical energy;
a cooling unit disposed on a backlighting side of the solar energy converting unit opposite to the light receiving surface to cool the solar energy converting unit;
an insulating heat conduction layer disposed between the solar energy converting unit and the cooling unit and configured to make the solar energy converting unit insulative relative to the cooling unit and transfer the heat of the solar energy converting unit to the cooling unit.

58. A photoelectrical and photo-thermal converting assembly, comprising:
a solar energy converting assembly comprising:
a photovoltaic power generating unit oriented in a way that a light receiving surface of the solar energy converting unit is configured to receive sunlight so as to convert optical energy into electrical energy;
a heat absorbing unit disposed on a backlighting side of the photovoltaic power generating unit opposite to the light receiving surface to absorb heat generated by the photovoltaic power generating unit during photoelectrical conversion;
an insulating heat conduction layer disposed between the photovoltaic power generating unit and the heat absorbing unit and configured to make the photovoltaic power generating unit insulative relative to the heat absorbing unit and simultaneously transfer the heat generated on the photovoltaic power generating unit due to the sunlight thermal radiation and the heat generated by the photovoltaic power generating unit from photovoltaic power generation to the heat absorbing unit;
an electrical output unit electrically connected with the photovoltaic power generating unit to receive electrical energy from the photovoltaic power generating unit and output it outside the photoelectrical and photo-thermal converting assembly in the form of electrical current;
a heat transfer unit fluidly communicated with the heat absorbing unit to provide a heat absorbing medium for the heat absorbing unit and output the medium in the heat absorbing unit already absorbing heat outside the photoelectrical and photo-thermal converting assembly.

59. The photoelectrical and photo-thermal converting assembly according to claim 58, wherein the electrical output unit of each photoelectrical and photo-thermal converting assemblies is connected in series with the electrical output unit of another photoelectrical and photo-thermal converting assemblies and then connected with an electrical output main line outside the photoelectrical and photo-thermal converting assemblies, and meanwhile, the heat transfer unit of each of the photoelectrical and photo-thermal converting assemblies is connected in parallel with the heat transfer unit of another photoelectrical and photo-thermal converting assemblies, and then connected with a heat exchange main line outside the photoelectrical and photo-thermal converting assemblies.
